(19) United States
(12) Patent Application Publication
(10) Pub. No.: US 2009/0216479 A1
(43) Pub. Date: Aug. 27, 2009

(54) METHOD AND APPARATUS FOR TESTING A POWER ENGINEERING DEVICE

(75) Inventor: Friedrich Kaufmann, Thueringerberg (AT)

Correspondence Address: Workman Nydegger;1000 Eagle Gate Tower, 60 East South Temple, Salt Lake City, UT, 84111, US

(73) Assignee: Omicron Electronics GmbH, Klaus (AT)

(21) Appl. No.: 12/392,273

(22) Filed: Feb. 25, 2009

(30) Foreign Application Priority Data
Feb. 25, 2008 (EP) 08 003 364.0

(51) Int. Cl. G06F 19/00; G01R 19/00

(52) U.S. Cl. 702/109

(57) ABSTRACT

A method and an apparatus for testing a power engineering device, for example a high-power transformer, are provided. A test signal is applied to the power engineering device, and this test signal, starting from an initial value, rises steadily and monotonically to a predetermined final value (U₀), and retains this final value (U₀) over a predetermined time interval.

### CROSS-REFERENCE TO RELATED APPLICATIONS

This application claims the benefit of earlier filed European Patent Application No. 08 003 364.0, filed Feb. 25, 2008, the disclosure of which is incorporated herein in its entirety.

### BACKGROUND OF THE INVENTION

1. The Field of the Invention

This invention concerns a method and an apparatus for testing power engineering devices.

2. Technology Review

Because of the constantly increasing pressure on costs, the energy business is forced to keep power engineering devices, such as high-power transformers, in use for as long as possible. For this reason, it is all the more important to test correct functioning of these power engineering devices as precisely as possible and with as short a measuring time as possible, to minimize the down time of the power engineering device.

According to the prior art, this test typically involves applying a sinusoidal or step-like test signal to the power engineering device, and then analyzing properties of the power engineering device on the basis of signal waveforms that result depending on the abruptly applied test signal. For instance, if the test signal is a step-like voltage applied to the power engineering device, a current caused by this step-like voltage is measured, from which specific conclusions about the properties of the power engineering device are possible. In practice, however, applying a step-like voltage, at least in the case of capacitive test objects, results in a very high peak current, causing metrological problems.

In general terms, the usual procedure according to the prior art, which involves applying a step-like test signal to the power engineering device, results in metrological problems in the measurement of the resulting signal waveforms.

### BRIEF SUMMARY OF THE INVENTION

According to the invention, a method of testing a power engineering device is provided. To test the power engineering device, a test signal is applied to the power engineering device, and a response of the power engineering device to the test signal is detected. This test signal has a waveform which, starting from an initial value, rises steadily and monotonically to a predetermined final value, and retains this final value over a predetermined time interval.

A steadily and monotonically rising waveform is understood as a waveform in which a rise of the signal per time unit is appropriately limited. A steadily rising signal waveform is not at all a step-like waveform. In other words, the steadily and monotonically rising waveform described herein is a waveform that runs more flatly than a step-like waveform, which is used according to the prior art and which is usually implemented by a high test signal value (a voltage) being applied suddenly to the power engineering device by means of a relay. Monotonically rising means that the waveform never drops within the predetermined interval.

Since the test signal has a steadily rising waveform, and in particular not a step-like waveform, the resulting measurement response advantageously has no peak, as is the case in the case of the step-like test signals. The resulting measurement response can therefore advantageously be measured in the initial area (i.e., from the start of the application of the test signal on), which according to the prior art is impossible because of the high initial value at the start.

According to an embodiment, the test signal is a voltage, by means of which a current is caused in the power engineering device, and its current waveform is measured. Then, from a ratio between a voltage waveform of this voltage and the resulting current waveform, at least one electrical property of the power engineering device can be determined.

According to a further embodiment, instead of the step which is used according to the prior art, a “soft step” is used, by which high charging currents at the start of the step response are avoided.

The electrical property of the power engineering device may, e.g., be an impedance (more precisely a frequency response of an impedance) of the power engineering device, although the invention is not limited to this particular embodiment.

According to a further embodiment, the electrical property is determined, in particular, for very low frequencies of less than 10 Hz.

In the method according to an embodiment of the invention, the test signal waveform, from the initial value to the final value, can be ramp-shaped, in the form of two parabolic arcs appended to each other, or semisinusoidal.

In this case the final value may be greater than 100 V, or more advantageously greater than 200 V, depending on the particular application and the respective test object.

The electrical property Z(s) of the test object can be determined from the voltage waveform u(t) and the current waveform i(t) by means of a Laplace transformation, as it is given in the following Equation (1):

$$Z ( s ) = \frac{L \{ u ( t ) \}}{L \{ i ( t ) \}} \qquad ( 1 )$$

provided that u(t)=0 and i(t)=0 for t<0.

According to an embodiment of the invention, the predetermined time interval in which the test signal retains the predetermined final value is in particular longer than 10 minutes and less than 5 hours.

The current waveform may be measured over a certain period (e.g., 10 minutes to 5 hours), and the further waveform, i.e., the waveform after the further period, may be extrapolated. A long measurement time may be recommendable if the frequency response of the impedance is to be measured even for quite low frequencies (e.g., at 0.0001 Hz).

It should be noted that the impedance or impedance function over the frequency of a two-pole network fully characterizes this two-pole network, so that from the impedance other electrical properties can also be derived.

With the method according to an embodiment of the invention, an insulation of the power engineering device, in particular an insulation of a high-power transformer, can be tested.

By measuring the impedance of the insulation of a high-power transformer, the electrical properties of this insulation, i.e., the water content in a solid part of the insulation (paper, pressboard), can be determined. In this way the quality of this insulation and thus the property of the high-power transformer can be determined.

According to an embodiment of the invention, an apparatus for testing a power engineering device is also provided. This apparatus is in such a form that the apparatus applies a test signal to the power engineering device. The apparatus lets the test signal rise from an initial value steadily and monotonically to a predetermined final value. This final value is then retained by the test signal over a predetermined time interval.

The advantages of the apparatus according to the invention correspond essentially to the advantages of the method according to the invention, which have been explained in detail above, so that a repetition is omitted here.

In an embodiment according to the invention, the apparatus includes a voltage generator, a voltage measurement device and an analysis device. The voltage generator generates the test signal in the form of a voltage, and applies this voltage to the power engineering device. The voltage measurement device measures a waveform of a current, which is caused by the voltage which the voltage generator applies, via the power engineering device. The analysis device forms a ratio from a voltage waveform of the voltage and the current waveform, and determines, depending on this ratio, an electrical property, e.g., the impedance or the frequency response of the impedance, of the power engineering device.

This invention is particularly suitable for measuring the electrical properties of an insulation in the case of high-power transformers. Expressed otherwise, by this invention the state of the insulation (e.g., oil and cellulose) can be tested, from which the decision about whether the transformer can or should be operated safely for longer can then be derived. Obviously, this invention is not restricted to this preferred application field. This invention can also be used, for instance, to evaluate insulations of underground cables which contain oil and paper insulations. Additionally, with this invention, critical lead-throughs for transformers can also be investigated. In general, the invention can also be used for material investigations outside the field of power engineering devices.

This invention is explained in more detail below, with reference to the attached drawings and on the basis of preferred embodiments.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 shows schematically an apparatus according to an embodiment of the invention for measuring an impedance;

FIG. 2a shows a voltage waveform according to an embodiment of the invention, and FIG. 2b shows a current waveform which is caused by it for an ideal capacitor;

FIG. 3a shows another voltage waveform according to another embodiment of the invention, and FIG. 3b shows a current waveform which is caused by it for an ideal capacitor;

FIG. 4a shows a further voltage waveform according to an embodiment of the invention, and FIG. 4b shows a current waveform which is caused by it for an ideal capacitor; and

FIG. 5 shows schematically an apparatus according to an embodiment of the invention for measuring an impedance of an insulation of a high-power transformer.

### DETAILED DESCRIPTION OF THE PREFERRED EMBODIMENTS

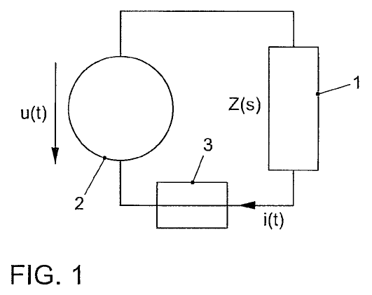

FIG. 1 shows schematically an arrangement according to the invention, comprising a voltage generator 2 and an ammeter 3 for determining an impedance of a device under test 1 (e.g., an insulation). From a current waveform i(t) which is measured by the ammeter 3 and a voltage waveform u(t) which is generated by the voltage generator 2, with a Laplace transformation the impedance Z(s) of the device under test 1 can be determined (see Equation 1 above).

The Laplace transformation transforms a given function f(t) from the real time domain into a function F(s) in the complex spectral domain (frequency domain), provided that u(t)=0 and i(t)=0 for t<0, as is indicated by the following Equation 2:

$$L \{ f ( t ) \} = \overline{F} ( s ) = {\int }_{0}^{∞} f ( t ) {e}^{- st} d t s ɛ C \qquad ( 2 )$$

If an ideal step with voltage U₀ is assumed for the voltage which the voltage generator 2 generates, the resulting Laplace transformation of the voltage is very simple, as is shown in Equation 3 given below:

$$L \{ u ( t ) \} = \frac{{U}_{0}}{s} \qquad ( 3 )$$

if u(t)=0 for t<0 and u(t)=U₀ for t≧0.

However in the practical case, it is found that for capacitive meter objects the current becomes very large (theoretically infinitely large) because of the step in the voltage, and is only limited by loss resistances. This current peak at the start of the current waveform can in practice not be measured correctly by the ammeter 3.

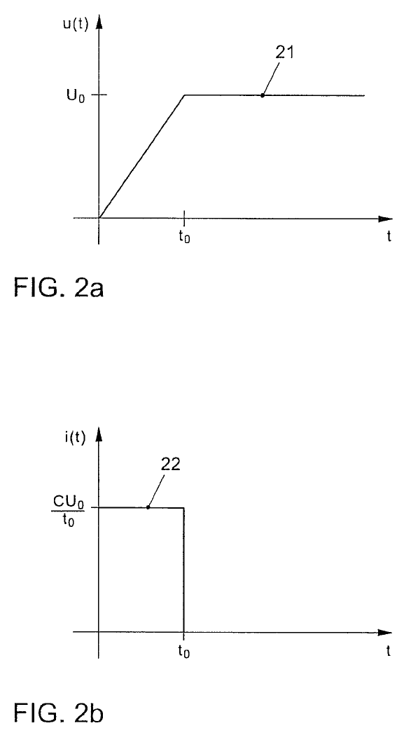

In FIG. 2a, a voltage waveform 21 according to an embodiment of the invention is shown. It is described by the following Equation (4):

$$\begin{matrix}u ( t ) = 0 & for t < 0 , \\ u ( t ) = \frac{{U}_{0}}{{t}_{0}} \times t & for 0 \leq t \leq {t}_{0} , \\ {U}_{0} & for t > {t}_{0} ,\end{matrix} \qquad ( 4 )$$

The predetermined time span t₀ may be longer than 100 ms but may be shorter than 1 minute. Also preferred is a time span t₀ of at least 5 s but a maximum of 10 s.

If the device under test 1 is an ideal capacitor, the result is the current waveform shown in FIG. 2b.

It is recognized that this current waveform advantageously has no current peak, as is the case for a step-like current waveform, which as already noted several times is used according to the prior art. Therefore, the current waveform shown in FIG. 2b can also be measured completely, including in the initial area, by the ammeter 3.

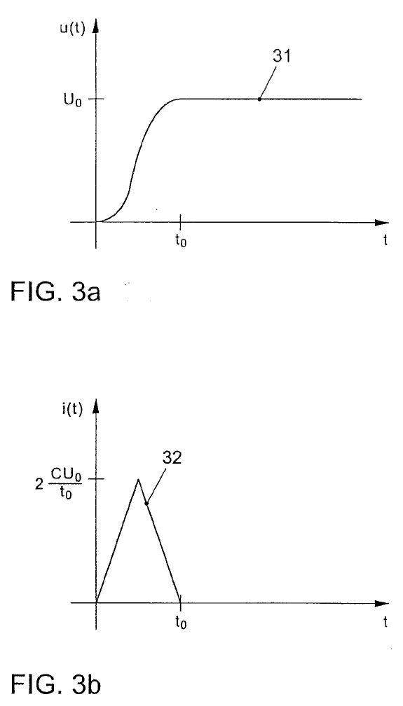

In FIG. 3a, another voltage waveform according to an embodiment of the invention, with a limited rise time of the voltage waveform over time, is shown. The voltage waveform consists of two parabolic arcs, and is described by the following Equation (5):

$$\begin{matrix}u ( t ) = 0 & for t < 0 , \\ u ( t ) = 2 {U}_{0} \times {( \frac{t}{{t}_{0}} )}^{2} & for 0 \leq t \leq \frac{{t}_{0}}{2} , \\ u ( t ) = {U}_{0} \times [ 1 - 2 \times {( 1 - \frac{t}{{t}_{0}} )}^{2} ] & for \frac{{t}_{0}}{2} \leq t \leq {t}_{0} , \\ {U}_{0} & for t > {t}_{0} .\end{matrix} \qquad ( 5 )$$

The predetermined time span to may again be longer than 100 ms but may be shorter than 1 minute. Also preferred is a time span t₀ of at least 5 s but a maximum of 10 s.

Again on an ideal capacitor, the result is a triangular current waveform 32, as shown in FIG. 3b. This current waveform 32 also has no current peak, as is the case according to the prior art with an applied step-like voltage. In comparison with the current waveform 22 shown in FIG. 2b, the current waveform 32 of FIG. 3b additionally has the advantage that the current waveform 32 is not step-like, as is the case with the current waveform 22 shown in FIG. 2b. The current waveform 32 can therefore be measured better or more precisely by the ammeter 3, in particular in the initial area.

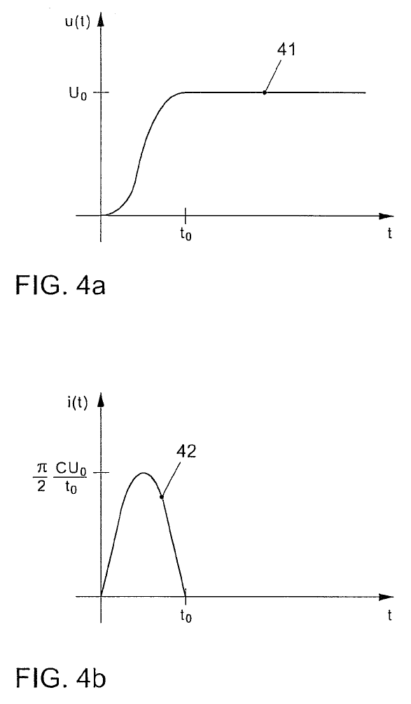

Finally, in FIG. 4a, another voltage waveform according to an embodiment of the invention is shown. It has a semisinusoidal rise, and is described by the following Equation 6:

$$\begin{matrix}u ( t ) = 0 & for t < 0 , \\ u ( t ) = {U}_{0} \times {sin}^{2} ( \frac{π}{2} \times \frac{t}{{t}_{0}} ) & for 0 \leq t \leq {t}_{0} , \\ {U}_{0} & for t > {t}_{0} .\end{matrix} \qquad ( 6 )$$

Again, the predetermined time span t₀ may be longer than 100 ms but shorter than 1 minute. Here too a time span t₀ of at least 5 s but a maximum of 10 s is preferred.

Also, U₀ preferably may be greater than 100 V and better greater than 200 V, which applies to all the embodiments shown in FIGS. 2 to 4.

In the case of an ideal capacitor, this voltage waveform 41 according to the invention results in the current waveform 42 shown in FIG. 4b, which again advantageously has no current peak such as is usual in the prior art. In contrast to the current waveform 22 shown in FIG. 2b, the current waveform 42 shown in FIG. 4b has no step, and additionally, in contrast to the current waveform 32 shown in FIG. 3b, it has the advantage that it comes to no abrupt change in the rise or fall of the current, as is the case with the current waveform 32 because of the peak of the triangle. Because the ammeter 3 can measure this peak of the triangle correctly only with difficulty, the current waveform 42 shown in FIG. 4b, and therefore the voltage waveform 41 shown in FIG. 4a, has an advantage compared with the embodiment shown in FIGS. 3a and 3b.

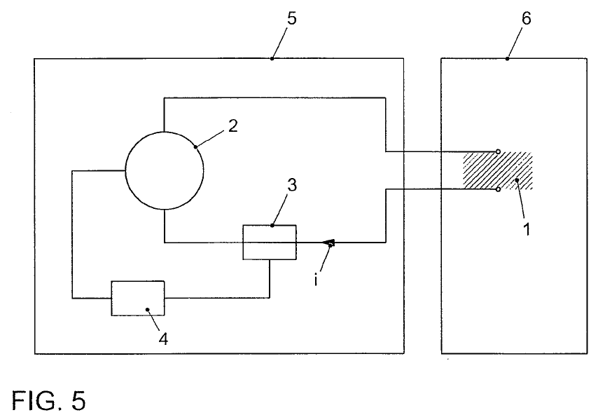

In FIG. 5, an embodiment of the invention of an apparatus 5 for determining an impedance of an insulator or insulation 1 of a high-power transformer 6 is shown.

The apparatus 5 includes a voltage generator 2, an ammeter 3 and an analysis device 4. Via the voltage generator 2, a voltage is applied to the insulation 1, and causes through the insulation 1 a current i, which is measured by the ammeter 3. From the ratio between the voltage waveform of the voltage which the voltage generator 2 generates and the current waveform which the ammeter 3 measures, the analysis device 4 determines an impedance of the insulation 1 for frequencies below 10 Hz. By knowing this impedance, which can also be called the frequency response of the insulation 1, different other electrical magnitudes can also be derived. These include, for instance, the dissipation factor tan(delta) depending on the frequency, via which dissipation factor, starting from known waveforms of this dissipation factor depending on the frequency at different humidity values of the insulation, conclusions can be drawn about the water content in the paper of the insulation 1.

A voltage waveform according to the invention, with limited rise rate, can also be generated in an embodiment (not shown) with a digital signal generator and a corresponding amplifier to generate the necessary voltages.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method of testing a power engineering device, comprising:
applying a test signal to the power engineering device, this test signal, starting from an initial value, rising steadily and monotonically to a predetermined final value and retaining this final value over a predetermined time interval; and
detecting a response of the power engineering device to the test signal.

2. The method according to claim 1, comprising
applying a voltage as the test signal,
measuring a current waveform over the power engineering device, and
determining from a ratio between a voltage waveform of the voltage and the current waveform an electrical property of the power engineering device.

3. The method according to claim 2, wherein the electrical property is determined for frequencies below 10 Hz.

4. The method according to claim 2, wherein the electrical property Z(s) is determined from the voltage waveform u(t) and the current waveform i(t) by means of a Laplace transformation, as follows:
$$Z ( s ) = \frac{L \{ u ( t ) \}}{L \{ i ( t ) \}} .$$

5. The method according to claim 2, wherein the voltage waveform u(t) over time fits the following relations:
$$\begin{matrix}u ( t ) = 0 & for t < 0 , \\ u ( t ) = \frac{{U}_{0}}{{t}_{0}} \times t & for 0 \leq t \leq {t}_{0} , \\ {U}_{0} & for t > {t}_{0} ,\end{matrix}$$
where U₀ is a predetermined voltage, and t₀ is a predetermined time span.

6. The method according to claim 2, wherein the voltage waveform u(t) over time t fits the following relations:
$$\begin{matrix}u ( t ) = 0 & for t < 0 , \\ u ( t ) = 2 {U}_{0} \times {( \frac{t}{{t}_{0}} )}^{2} & for 0 \leq t \leq \frac{{t}_{0}}{2} , \\ u ( t ) = {U}_{0} \times [ 1 - 2 \times {( 1 - \frac{t}{{t}_{0}} )}^{2} ] & for \frac{{t}_{0}}{2} \leq t \leq {t}_{0} , \\ {U}_{0} & for t > {t}_{0} ,\end{matrix}$$
where U₀ is a predetermined voltage, and t₀ is a predetermined time span.

7. The method according to claim 2, wherein the voltage waveform u(t) over time fits the following relations:
$$\begin{matrix}u ( t ) = 0 & for t < 0 , \\ u ( t ) = {U}_{0} \times {sin}^{2} ( \frac{π}{2} \times \frac{t}{{t}_{0}} ) & for 0 \leq t \leq {t}_{0} , \\ {U}_{0} & for t > {t}_{0} ,\end{matrix}$$
where U₀ is a predetermined voltage, and t₀ is a predetermined time span.

8. The method according to claim 5, wherein U₀ is greater than 100 V.

9. The method according to claim 5, wherein t₀ is longer than 100 ms.

10. The method according to claim 1, wherein the predetermined time interval is longer than 10 minutes.

11. The method according to claim 1, wherein an insulation of the power engineering device is tested.

12. The method according to claim 1, wherein the power engineering device is a high-power transformer.

13. The method according to claim 1, wherein an impedance of the power engineering device is determined from the response of the power engineering device.

14. An apparatus for testing a power engineering device, comprising:
a test signal generator for applying a test signal to the power engineering device in such a way that the test signal rises from an initial value steadily and monotonically to a predetermined final value, and retains this final value over a predetermined time interval; and
a measuring device for detecting a response of the power engineering device to the test signal.

15. The apparatus according to claim 14,
wherein the apparatus includes a voltage generator as the test signal generator, a voltage measurement device and an analysis device,
the voltage generator generating a voltage as the test signal, and applying it as the voltage to the power engineering device,
the voltage measurement device measuring a current waveform via the power engineering device, and
the analysis device, from a ratio from a voltage waveform of the voltage and the current waveform, determining an electrical property of the power engineering device.

16. The apparatus according to claim 14, wherein the apparatus is designed to:
apply a test signal to a power engineering device, this test signal, starting from an initial value, rising steadily and monotonically to a predetermined final value and retaining this final value over a predetermined time interval; and
detect a response of the power engineering device to the test signal.

17. The apparatus according to claim 16, wherein the apparatus is further designed to:
apply a voltage as the test signal,
measure a current waveform over the power engineering device, and
determine from a ratio between a voltage waveform of the voltage and the current waveform an electrical property of the power engineering device.

18. The apparatus according to claim 16, wherein the apparatus is designed so that:
the electrical property Z(s) is determined from the voltage waveform u(t) and the current waveform i(t) by means of a Laplace transformation, as follows:
$$Z ( s ) = \frac{L \{ u ( t ) \}}{L \{ i ( t ) \}} .$$

19. The apparatus according to claim 14, wherein the apparatus is designed so that:
the voltage waveform u(t) over time fits in the following relations:
$$\begin{matrix}u ( t ) = 0 & for t < 0 , \\ u ( t ) = \frac{{U}_{0}}{{t}_{0}} \times t & for 0 \leq t \leq {t}_{0} , \\ {U}_{0} & for t > {t}_{0} ,\end{matrix}$$
where U₀ is a predetermined voltage, and t₀ is a predetermined time span.

20. The apparatus according to claim 14, wherein the apparatus is designed so that:
the voltage waveform u(t) over time t fits the following relations:
$$\begin{matrix}u ( t ) = 0 & for t < 0 , \\ u ( t ) = 2 {U}_{0} \times {( \frac{t}{{t}_{0}} )}^{2} & for 0 \leq t \leq \frac{{t}_{0}}{2} , \\ u ( t ) = {U}_{0} \times [ 1 - 2 \times {( 1 - \frac{t}{{t}_{0}} )}^{2} ] & for \frac{{t}_{0}}{2} \leq t \leq {t}_{0} , \\ {U}_{0} & for t > {t}_{0} ,\end{matrix}$$
where U₀ is a predetermined voltage, and t₀ is a predetermined time span.
